(19) United States
(12) Patent Application Publication
(10) Pub. No.: US 2024/0222286 A1
(43) Pub. Date: Jul. 4, 2024

(54) HYBRID BONDED DIE-LAST INTERCONNECT ARCHITECTURES

(71) Applicant: Intel Corporation, Santa Clara, CA (US)

(72) Inventors: Mohammad Mamunur RAHMAN, Gilbert, AZ (US); Brandon C. MARIN, Gilbert, AZ (US); Gang DUAN, Chandler, AZ (US)

(21) Appl. No.: 18/091,014

(22) Filed: Dec. 29, 2022

(51) Int. Cl. H01L 23/538; H01L 23/00; H01L 25/00; H01L 25/065

(52) U.S. Cl. CPC H01L 23/5389; H01L 23/5385; H01L 24/05; H01L 24/08; H01L 24/09; H01L 24/80; H01L 24/95; H01L 25/0655; H01L 25/50; H01L 23/481

(57) ABSTRACT

Embodiments disclosed herein include electronic packages and methods of forming electronic packages. In an embodiment, the electronic package comprises a die layer, with a first side and a second side opposite from the first side. In an embodiment, the die layer comprises a first die, and a second die. In an embodiment, a bridge is on the first side of the die layer, where the bridge communicatively couples the first die to the second die. In an embodiment, electrically conductive routing is on the second side of the die layer.

### TECHNICAL FIELD

Embodiments of the present disclosure relate to electronic packages, and more particularly to package architectures that include a die-last interconnect integration with an organic bridge or an embedded bridge.

### BACKGROUND

In advanced packaging applications, a plurality of dies are communicatively coupled together in order to function as a single, larger capacity, system. This allows for the size of the dies to be reduced, thereby reducing costs due to improved yield. However, more dies being integrated into a single system provides new challenges for package integration. In one approach, a plurality of bridge dies can be coupled between pairs of dies. As the number of dies increases, the complexity of interconnecting them with bridge dies also increases. For example, warpage, misalignment, and the like may render multi-bridge architectures unattractive from a high volume manufacturing perspective.

However, embedded bridge architectures are not without issue. One particularly challenging design consideration is the presence of different sized bumps. For example, the bumps for the embedded bridge may be approximately 45 μm to approximately 55 μm, whereas the core bumps may be double that size. This causes a bump thickness variation (rBTV) challenge for assembly and limits the scaling possible for the embedded bridges.

In some instances a die-first approach can be used to assemble multi-die packages. However, as the name suggests, die-first approaches require the die to be put into the assembly before the routing and/or packaging is completed. As such, any yield loss during the packaging operation will be very expensive.

### BRIEF DESCRIPTION OF THE DRAWINGS

FIG. 1 is a cross-sectional illustration of an electronic package that includes a die layer with high density patterning (HDP) layers that are provided on one side of the die layer and power delivery circuitry that is provided on the opposite side of the die layer, in accordance with an embodiment.

FIG. 2 is a cross-sectional illustration of an electronic package that includes a die layer with bridge dies on one side of the die layer and power delivery circuitry that is provided on the opposite side of the die layer, in accordance with an embodiment.

FIG. 3A is a cross-sectional illustration of a HDP layers that are provided over a first carrier, in accordance with an embodiment.

FIG. 3B is a cross-sectional illustration of power delivery circuitry that is provided over a second carrier, in accordance with an embodiment.

FIG. 3C is a cross-sectional illustration of the second carrier after a plurality of dies are coupled to the power delivery circuitry, in accordance with an embodiment.

FIG. 3D is a cross-sectional illustration of the second carrier after the plurality of dies are embedded in a dielectric layer, in accordance with an embodiment.

FIG. 3E is a cross-sectional illustration of the electronic package after the plurality of dies are coupled to the HDP layers through hybrid bonding, in accordance with an embodiment.

FIG. 3F is a cross-sectional illustration of the electronic package after it is coupled to a board, in accordance with an embodiment.

FIG. 4A is a cross-sectional illustration of a first carrier with bridge dies embedded in a dielectric layer over the first carrier, in accordance with an embodiment.

FIG. 4B is a cross-sectional illustration of power delivery circuitry that is provided over a second carrier, in accordance with an embodiment.

FIG. 4C is a cross-sectional illustration of the second carrier after a plurality of dies are coupled to the power delivery circuitry, in accordance with an embodiment.

FIG. 4D is a cross-sectional illustration of the second carrier after the plurality of dies are embedded in a dielectric layer, in accordance with an embodiment.

FIG. 4E is a cross-sectional illustration of the electronic package after the plurality of dies are coupled to the bridge dies through hybrid bonding, in accordance with an embodiment.

FIG. 5 is a cross-sectional illustration of an electronic system with a die layer with bridge dies on one side and power delivery circuitry on the opposite side, in accordance with an embodiment.

FIG. 6 is a schematic of a computing device built in accordance with an embodiment.

### EMBODIMENTS OF THE PRESENT DISCLOSURE

Described herein are package architectures that include a die-last interconnect integration with an organic bridge or an embedded bridge, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, existing multi-die integration solutions are limited with respect to future scaling to smaller pitches and features. Current solutions also limit the benefits of known good die assembly techniques. Accordingly, embodiments disclosed herein include architectures that include hybrid bonding approaches. A known good die solution is also enabled since the dies are integrated into the system last in a “die-last” approach. Further, embodiments include providing the bridging circuitry (e.g., high density patterning (HDP) architectures or embedded bridge architectures) on the opposite side of the die layer from the power delivery circuitry. As such, there is no need for pillar like vias or through silicon vias (TSVs) through the bridging circuitry. This further reduces complexity and cost of the integration scheme. Further, the issues with non-uniform bump sizes (e.g., smaller bridge bumps and larger core bumps) is addressed. Particularly, the larger pitch and size power delivery bumps are provided on one side and the finer routing bumps for the embedded bridge are moved to the opposite side. This allows scaling to smaller bump sizes to be done more easily.

In certain embodiments, the bridging circuitry is provided on a first carrier (e.g., a glass carrier), and the power delivery circuitry and the dies are provided on a second carrier (e.g., a glass carrier). The two carriers and their components are then brought together and bonded with a hybrid bonding architecture. A hybrid bonding architecture may refer to a bonding solution that includes the direct bonding of two or more interfaces with different materials. For example, first interfaces may include a copper-to-copper bond and second interfaces may include a dielectric-to-dielectric bond or a dielectric-to-silicon bond. That is, the hybrid bonding approach may be implemented without the need for solder interconnects or the like, and allows for directly bonding components together. This enables further reductions in interconnect pitch and feature size needed for further scaling in advanced packaging architectures.

The die-last solution involves fabricating both the bridging circuitry and the power delivery circuitry before the expensive compute dies are integrated into the system. After the bridging circuitry and the power delivery circuitry are determined to be correctly formed, known good dies can be assembled to the power delivery circuitry and subsequently communicatively coupled together by the bridging circuitry. In this manner assembled systems will have a higher yield and allow for reductions in cost of assembly.

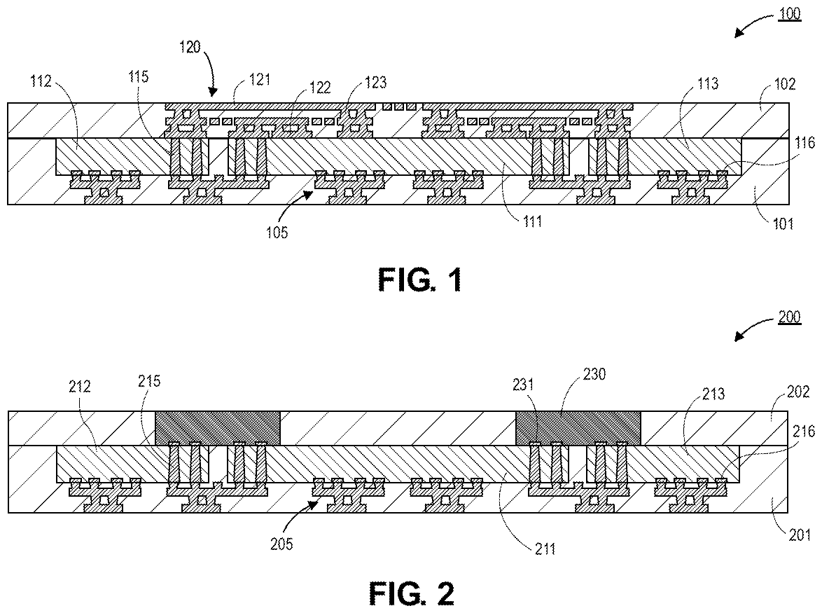

Referring now to FIG. 1, a cross-sectional illustration of an electronic package 100 is shown, in accordance with an embodiment. In an embodiment, the electronic package 100 may comprise a die layer. The die layer may comprise two or more compute dies that are laterally adjacent to each other. In the illustrated embodiment, a set of three dies 111, 112, and 113 are provided as an example. In an embodiment, the dies 111, 112, and 113 may be any type of compute die or memory die. For example, the dies 111, 112, and 113 may comprise one or more of central processing units (CPUs), graphics processing units (GPUs), systems on a chip (SoC), application specific integrated circuits (ASICs), communication dies, and the like. In a particular embodiment, the dies 111, 112, and 113 may be substantially similar to each other. For example, the dies 111, 112, and 113 may be considered die tiles that are interconnected with each other to provide a computing system with more capacity or otherwise improved performance.

In an embodiment, the dies 111, 112, and 113 may be embedded in a first dielectric layer 101. The first dielectric layer 101 may be a buildup film, silicon oxide, silicon nitride, or any other suitable dielectric material for hybrid bonding applications. As will be described in greater detail below, the first dielectric layer 101 may be a two part system, with a first portion embedding the power delivery circuitry 105 and a second portion embedding the dies 111, 112, and 113. As shown in FIG. 1, the dielectric layer 101 is entirely formed with a single material.

In an embodiment, the dies 111, 112, and 113 may have a first side and a second side opposite from the first side. In the illustrated embodiment, power delivery circuitry 105 is provided on the first side of the dies 111, 112, and 113, and bridging circuitry 120 is provided on the second side of the dies 111, 112, and 113. The dies 111, 112, and 113 may further comprise TSVs 115 or the like in order to communicatively couple the backside of the dies 111, 112, and 113 to the front side of the dies 111, 112, and 113.

In an embodiment, the power delivery circuitry 105 may include traces, pads, vias, and the like that are provided within the first dielectric layer 101. The power delivery circuitry 105 may be fabricated on a dimensionally stable and highly planar carrier, such as a glass carrier. As such, fine pitch and feature size is enabled. The power delivery circuitry 105 may be coupled to external power supplies, power regulation circuitry, and the like in order to provide power to the dies 111, 112, and 113. The power delivery circuitry 105 may be hybrid bonded to pads 116 on the dies 111, 112, and 113. As such, there may not be a need for solder interconnects between the dies 111, 112, and 113 and the power delivery circuitry 105.

In an embodiment, the bridging circuitry 120 may be provided over the dies 111, 112, and 113. The bridging circuitry 120 may be embedded in a second dielectric layer 102. The second dielectric layer 102 may be a material that enables hybrid bonding to the dies 111, 112, and 113. For example, the second dielectric layer 102 may comprise buildup film, silicon oxide, silicon nitride, or the like. In a particular embodiment, the second dielectric layer 102 is the same material as the top portion of the first dielectric layer 101.

The bridging circuitry 120 may comprise HDP conductive features, such as traces 121, pads 122, and vias 123. The bridging circuitry 120 may be configured so that one end is coupled to the first die 111 and a second end is coupled to the second die 112, or so that one end is coupled to the first die 111 and a second end is coupled to the third die 113. In this way, the dies 111, 112, and 113 may be communicatively coupled to each other. In some embodiments, the bridging circuitry 120 is hybrid bonded to one or more TSVs 115 through the dies 111, 112, and 113. As such, there may not be a need for solder or other intervening interconnects between the bridging circuitry 120 and the dies 111, 112, and 113.

In an embodiment, the bridging circuitry 120 may initially be assembled on a second dimensionally stable and highly planar carrier, such as glass. As such, the pitch and feature size of the bridging circuitry 120 can be scaled to smaller dimensions than existing packaging architectures. Further, since the power delivery circuitry is provided on the opposite side of the dies 111, 112, and 113, there is no need for pillar like vias that pass through the second dielectric layer 102 adjacent to or through the bridging circuitry 120.

Referring now to FIG. 2, a cross-sectional illustration of an electronic package 200 is shown, in accordance with an additional embodiment. In an embodiment, the electronic package 200 may comprise a die layer. The die layer may comprise two or more compute dies that are laterally adjacent to each other. In the illustrated embodiment, a set of three dies 211, 212, and 213 are provided as an example. In an embodiment, the dies 211, 212, and 213 may be any type of compute die or memory die. For example, the dies 211, 212, and 213 may comprise one or more CPUs, GPUs, SoCs, ASICs, communication dies, and the like. In a particular embodiment, the dies 211, 212, and 213 may be substantially similar to each other. For example, the dies 211, 212, and 213 may be considered die tiles that are interconnected with each other to provide a computing system with more capacity or otherwise improved performance.

In an embodiment, the dies 211, 212, and 213 may be embedded in a first dielectric layer 201. The first dielectric layer 201 may be a buildup film, silicon oxide, silicon nitride, or any other suitable dielectric material for hybrid bonding applications. As will be described in greater detail below, the first dielectric layer 201 may be a two part system, with a first portion embedding the power delivery circuitry 205 and a second portion embedding the dies 211, 212, and 213. As shown in FIG. 2, the dielectric layer 201 is entirely formed with a single material.

In an embodiment, the dies 211, 212, and 213 may have a first side and a second side opposite from the first side. In the illustrated embodiment, power delivery circuitry 205 is provided on the first side of the dies 211, 212, and 213, and bridging circuitry, such as a bridge die 230, is provided on the second side of the dies 211, 212, and 213. The dies 211, 212, and 213 may further comprise TSVs 215 or the like in order to communicatively couple the backside of the dies 211, 212, and 213 to the front side of the dies 211, 212, and 213.

In an embodiment, the power delivery circuitry 205 may include traces, pads, vias, and the like that are provided within the first dielectric layer 201. The power delivery circuitry 205 may be fabricated on a dimensionally stable and highly planar carrier, such as a glass carrier. As such, fine pitch and feature size is enabled. The power delivery circuitry 205 may be coupled to external power supplies, power regulation circuitry, and the like in order to provide power to the dies 211, 212, and 213. The power delivery circuitry 205 may be hybrid bonded to pads 216 on the dies 211, 212, and 213. As such, there may not be a need for solder interconnects between the dies 211, 212, and 213 and the power delivery circuitry 205.

In an embodiment, the bridge dies 230 may be provided over the dies 211, 212, and 213. The bridge dies 230 may be embedded in a second dielectric layer 202. The second dielectric layer 202 may be a material that enables hybrid bonding to the dies 211, 212, and 213. For example, the second dielectric layer 202 may comprise buildup film, silicon oxide, silicon nitride, or the like. In a particular embodiment, the second dielectric layer 202 is the same material as the top portion of the first dielectric layer 201.

The bridge dies 230 may comprise narrow line/space traces (not shown) that electrically couples one side of the bridge die 230 to the other side of the bridge die 230. The bridge dies 230 may be configured so that one end is coupled to the first die 211 and a second end is coupled to the second die 212, or so that one end is coupled to the first die 211 and a second end is coupled to the third die 213. In this way, the dies 211, 212, and 213 may be communicatively coupled to each other. In some embodiments, the bridge dies 230 are hybrid bonded to one or more TSVs 215 through the dies 211, 212, and 213. As such, there may not be a need for solder or other intervening interconnects between the bridge dies 230 and the dies 211, 212, and 213.

In an embodiment, the bridge dies 230 may initially be assembled on a second dimensionally stable and highly planar carrier, such as glass. As such, the alignment of the bridge dies 230 is improved so that scaling to smaller dimensions than existing packaging architectures is enabled. Further, since the power delivery circuitry is provided on the opposite side of the dies 211, 212, and 213, there is no need for TSVs that pass through the bridge dies 230. This further reduces cost of the bridge dies 230 compared to existing solutions where the bridge dies 230 and the power delivery is provided on the same side of the dies 211, 212, and 213.

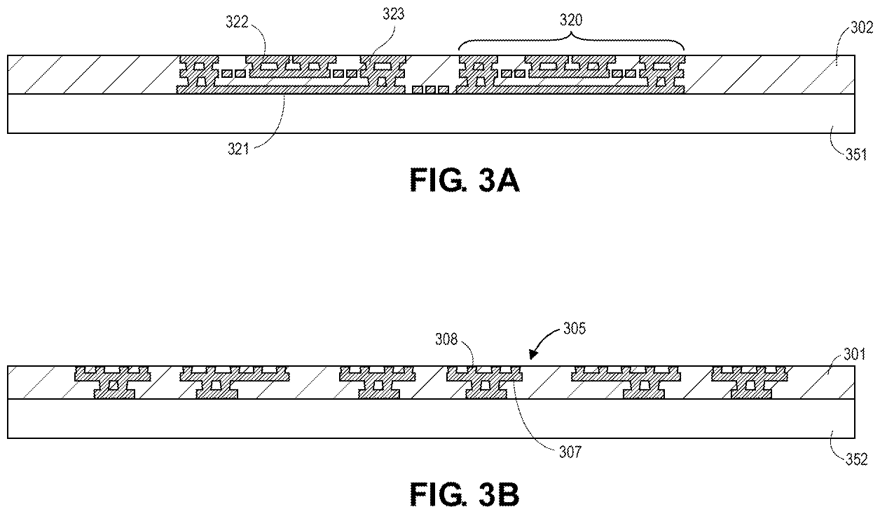

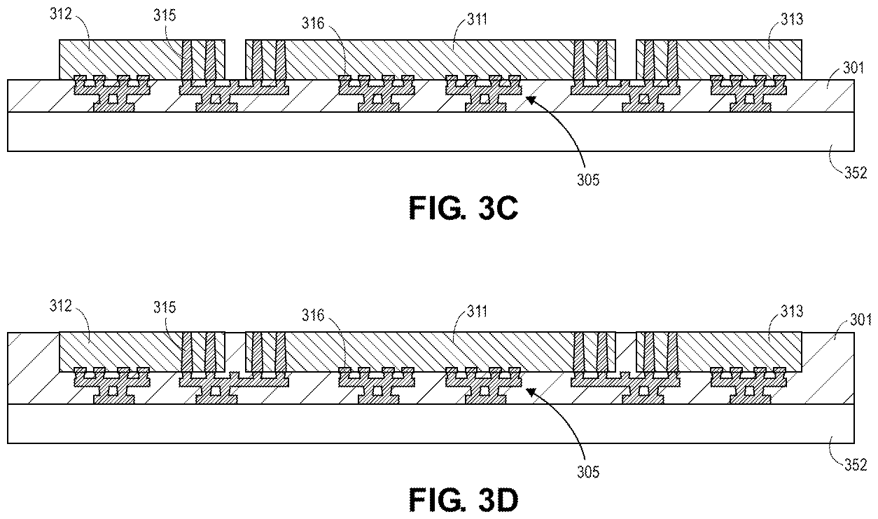

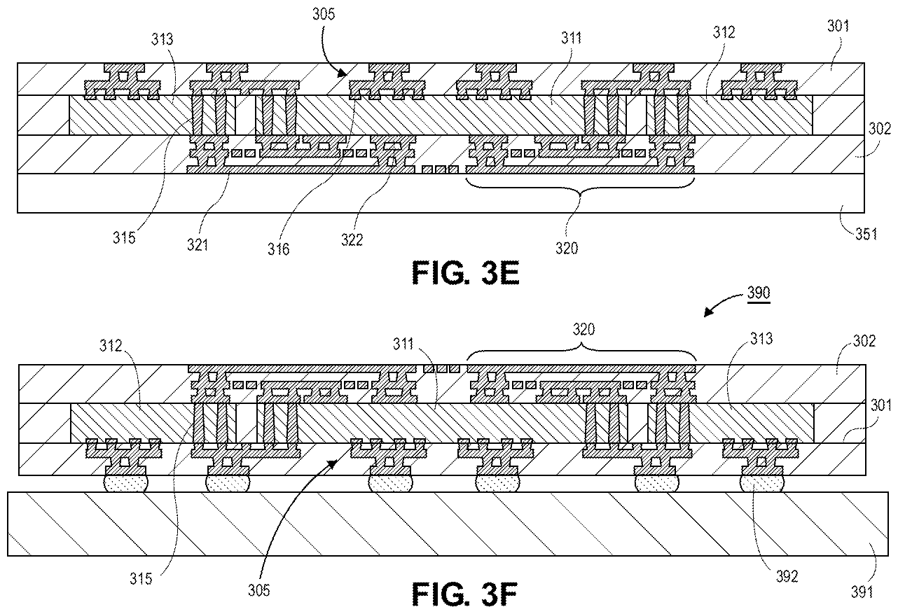

Referring now to FIGS. 3A-3E, a series of cross-sectional illustrations depicting a process for forming an electronic package similar to the electronic package 100 shown in FIG. 1 is shown, in accordance with an embodiment. In an embodiment, the electronic package shown in FIGS. 3A-3E is formed with a die-last approach. That is, at least the power delivery circuitry is formed before the attachment of the dies. In some instances, both the power delivery circuitry and the bridging circuitry is formed before the dies are attached to the system. Further, hybrid bonding solutions described herein allow for further scaling to smaller pitch and feature sizes.

Referring now to FIG. 3A, a cross-sectional illustration of a first carrier 351 is shown, in accordance with an embodiment. In an embodiment, the first carrier 351 may be a dimensionally stable and highly planar material. In some embodiments, the first carrier 351 may comprise glass, silicon, or the like. The first carrier 351 may be a reusable substrate. That is, after the fabrication of the package substrate, the first carrier 351 may be detached and reused.

In an embodiment, bridging circuitry 320 may be fabricated on the first carrier 351. The bridging circuitry 320 may comprise traces 321, pads 322, and vias 323. In the illustrated embodiment, a pair of two bridging circuitries 320 are shown. Though, additional iterations of the bridging circuitry 320 may be included in order to communicatively couple more dies together than the three that will be shown in FIGS. 3A-3E. In an embodiment, the bridging circuitry 320 may be embedded in and/or provided on a second dielectric layer 302. The second dielectric layer 302 may comprise buildup film, silicon oxide, silicon nitride, or any other suitable dielectric material that is compatible with hybrid bonding architectures. In an embodiment, the top surface of the second dielectric layer 302 may be substantially coplanar with a topmost surfaces of pads 322.

The bridging circuitry 320 may be formed with HDP solutions. For example, line/space dimensions may be 10 μm/10 μm or smaller, or even 2 μm/2 μm or smaller. The high density line/space dimensions of the bridging circuitry 320 allow for a greater number of interconnects to be provided between dies. The fine line/space dimensions may be at least partially attributable to the planarity and dimensional stability of the underlying first carrier 351.

Referring now to FIG. 3B, a cross-sectional illustration of a second carrier 352 is shown, in accordance with an embodiment. In an embodiment, the second carrier 352 may be a dimensionally stable and highly planar material. In some embodiments, the second carrier 352 may comprise glass, silicon, or the like. The second carrier 352 may be a reusable substrate. That is, after the fabrication of the package substrate, the second carrier 352 may be detached and reused. The second carrier 352 may be the same material as the first carrier 351.

In an embodiment, power delivery circuitry 305 may be provided over the second carrier 352. The power delivery circuitry 305 may comprise pads 307, vias 308, traces (not shown), and the like. The power delivery circuitry 305 may be embedded in and/or provided on a first dielectric layer 301. The first dielectric layer 301 may comprise buildup film, silicon oxide, silicon nitride, or any other suitable dielectric material. In an embodiment, a top surface of the first dielectric layer 301 and the topmost surface of the vias 308 may be substantially coplanar with each other.

In an embodiment, the power delivery circuitry 305 may be formed with HDP processes. As such, fine line/space dimensions may be enabled. In some embodiments, the line/space dimensions of the power delivery circuitry 305 may be greater than the line/space dimensions of the bridging circuitry 320. Though in other embodiments, the line/space dimensions of the power delivery circuitry 305 may be substantially similar to or smaller than the line/space dimensions of the bridging circuitry 320.

Referring now to FIG. 3C, a cross-sectional illustration of the second carrier 352 after dies 311, 312, and 313 are attached to the power delivery circuitry 305 is shown, in accordance with an embodiment. In the illustrated embodiment, a set of three dies 311, 312, and 313 are shown. Though, it is to be appreciated that two or more dies may be used in some embodiments. In an embodiment, the dies 311, 312, and 313 are substantially similar to each other and are to be communicatively coupled to each other to provide improved capacity or otherwise improved performance. The dies 311, 312, and 313 may be any type of compute die, such as CPUs, GPUs, SoCs, ASICs, communication dies, or the like.

In an embodiment, the dies 311, 312, and 313 may include TSVs 315. The TSVs 315 allow for communicatively coupling the backside of the dies 311, 312, and 313 to the front side of the dies 311, 312, and 313. As such, communicative coupling by the bridging circuitry 320 on the backside of the dies 311, 312, and 313 is enabled. In an embodiment, the dies 311, 312, and 313 may further comprise pads 316. The pads 316 may be coupled to the vias 308 or pads 307 of the power delivery circuitry 305. In an embodiment, the pads 316 may be hybrid bonded to the power delivery circuitry 305. Though, solder or the like may be used in some embodiments.

In an embodiment, the addition of the dies 311, 312, and 313 at this point in the process flow may be referred to as being a die-last approach. That is, at least the power delivery circuitry 305 is fabricated before the dies 311, 312, and 313 are attached to the system. This enables both known-good power delivery circuitry 305 and known-good dies 311, 312, and 313 to be provided in order to improve yield and reduce costs of assembly. In some embodiments, the bridging circuitry 320 is also formed before the dies 311, 312, and 313 are attached to the system.

Referring now to FIG. 3D, a cross-sectional illustration of the second carrier 352 after the first dielectric layer 301 is extended in order to embed the dies 311, 312, and 313 is shown, in accordance with an embodiment. In the illustrated embodiment, the first dielectric layer 301 is shown as a single material. Though, in other embodiments, the portion of the first dielectric layer 301 that embeds the dies 311, 312, and 313 may be a different material than the portion of the first dielectric layer 301 that embeds the power delivery circuitry 305. The remaining portion of the first dielectric layer 301 may be applied with a lamination process or other deposition process. The first dielectric layer 301 may then be planarized so that a backside of the dies 311, 312, and 313 is substantially coplanar with the top surface of the first dielectric layer 301. The planarization may improve hybrid bonding in a subsequent processing operation shown in FIG. 3E.

Referring now to FIG. 3E, a cross-sectional illustration of the electronic package after the bridging circuitry 320 is bonded to the dies 311, 312, and 313 is shown, in accordance with an embodiment. As shown, the second carrier 352 is removed. The second carrier 352 may be removed after the bonding process between the bridging circuitry 320 and the dies 311, 312, and 313. In an embodiment, the first carrier 351 may also be removed after the bonding process. In an embodiment, the bonding process may be a hybrid bonding process that couples the bridging circuitry 320 to the TSVs 315 with a copper-to-copper bond. The second dielectric layer 302 may be bonded to the first dielectric layer 301 and/or the dies 311, 312, and 313.

Referring now to FIG. 3F, a cross-sectional illustration of a computing system 390 is shown, in accordance with an embodiment. In an embodiment, the computing system 390 comprises a board 391, such as a printed circuit board (PCB). The board 391 may be coupled to an electronic package by interconnects 392. The interconnects 392 are shown as being solder balls, but it is to be appreciated that any interconnect 392 architecture may be used in various embodiments.

In an embodiment, the electronic package comprises a first dielectric layer 301 and a second dielectric layer 302. In the first dielectric layer 301, a row of dies 311, 312, and 313 may be provided over power delivery circuitry 305. The dies 311, 312, and 313 may include TSVs 315. In an embodiment, three dies 311, 312, and 313 are shown, but it is to be appreciated that any number of dies may be used in some embodiments. The dies 311, 312, and 313 may be compute dies, such as CPUs, GPUs, SoCs, ASICs, communication dies, or the like.

In an embodiment, bridging circuitry 320 may be provided over the dies 311, 312, and 313 in the second dielectric layer 302. The bridging circuitry 320 may include pads that are bonded to the TSVs 315. For example, a hybrid bonding process may be used in some embodiments. In an embodiment, the bridging circuitry 320 communicatively couple the dies 311, 312, and 313 together.

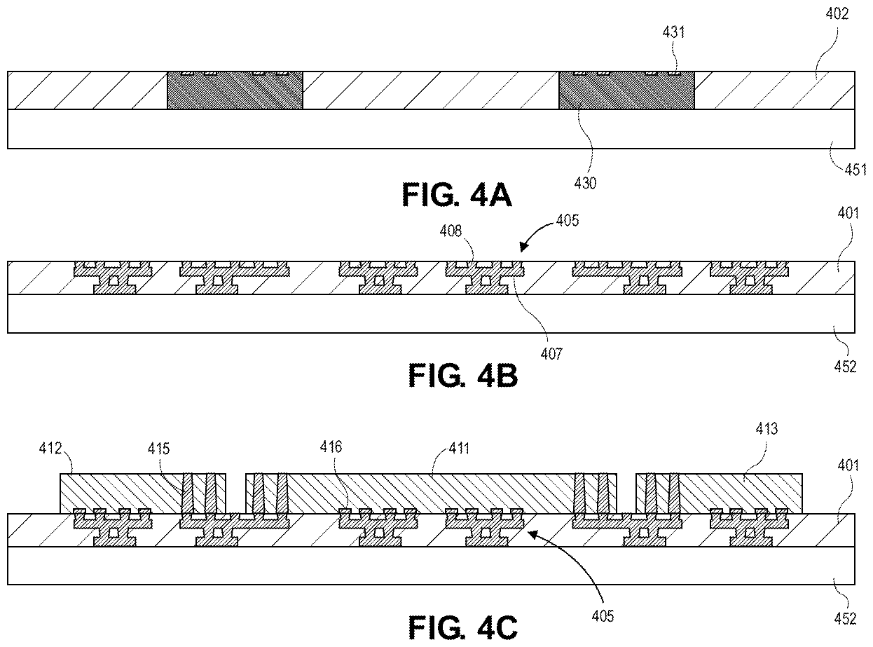

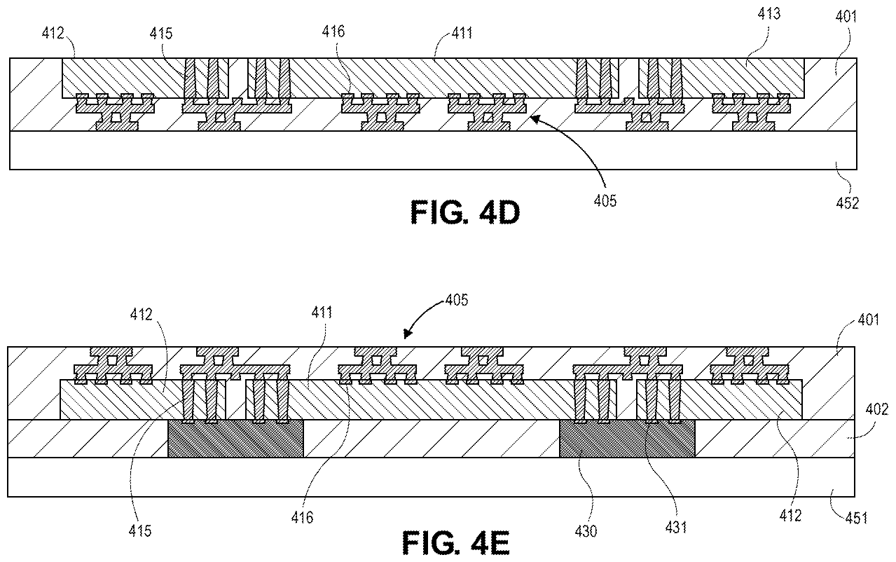

Referring now to FIGS. 4A-4E, a series of cross-sectional illustrations depicting a process for forming an electronic package similar to the electronic package 200 shown in FIG. 2 is shown, in accordance with an embodiment. In an embodiment, the electronic package shown in FIGS. 4A-4E is formed with a die-last approach. That is, at least the power delivery circuitry is formed before the attachment of the dies. In some instances, both the power delivery circuitry and the bridging circuitry is formed before the dies are attached to the system. Further, hybrid bonding solutions described herein allow for further scaling to smaller pitch and feature sizes.

Referring now to FIG. 4A, a cross-sectional illustration of a first carrier 451 is shown, in accordance with an embodiment. In an embodiment, the first carrier 451 may be a dimensionally stable and highly planar material. In some embodiments, the first carrier 451 may comprise glass, silicon, or the like. The first carrier 451 may be a reusable substrate. That is, after the fabrication of the package substrate, the first carrier 451 may be detached and reused.

In an embodiment, bridge dies 430 may be placed on the first carrier 451 (e.g., with a pick-and-place process). The bridge dies 430 may comprise pads 431. The bridge dies 430 may further comprise fine line/space routing (not shown). In the illustrated embodiment, a pair of two bridge dies 430 are shown. Though, additional iterations of the bridge dies 430 may be included in order to communicatively couple more dies together than the three that will be shown in FIGS. 4A-4E. In an embodiment, the bridge dies 430 may be embedded in a second dielectric layer 402. The second dielectric layer 402 may comprise buildup film, silicon oxide, silicon nitride, or any other suitable dielectric material that is compatible with hybrid bonding architectures. In an embodiment, the top surface of the second dielectric layer 402 may be substantially coplanar with a topmost surfaces of pads 431. The bridge dies 430 may have line/space dimensions that are 10 μm/10 μm or smaller, or even 2 μm/2 μm or smaller. The high density line/space dimensions of the bridge dies 430 allow for a greater number of interconnects to be provided between dies.

Referring now to FIG. 4B, a cross-sectional illustration of a second carrier 452 is shown, in accordance with an embodiment. In an embodiment, the second carrier 452 may be a dimensionally stable and highly planar material. In some embodiments, the second carrier 452 may comprise glass, silicon, or the like. The second carrier 452 may be a reusable substrate. That is, after the fabrication of the package substrate, the second carrier 452 may be detached and reused. The second carrier 452 may be the same material as the first carrier 451.

In an embodiment, power delivery circuitry 405 may be provided over the second carrier 452. The power delivery circuitry 405 may comprise pads 407, vias 408, traces (not shown), and the like. The power delivery circuitry 405 may be embedded in and/or provided on a first dielectric layer 401. The first dielectric layer 401 may comprise buildup film, silicon oxide, silicon nitride, or any other suitable dielectric material. In an embodiment, a top surface of the first dielectric layer 401 and the topmost surface of the vias 408 may be substantially coplanar with each other. In an embodiment, the power delivery circuitry 405 may be formed with HDP processes. As such, fine line/space dimensions may be enabled.

Referring now to FIG. 4C, a cross-sectional illustration of the second carrier 452 after dies 411, 412, and 413 are attached to the power delivery circuitry 405 is shown, in accordance with an embodiment. In the illustrated embodiment, a set of three dies 411, 412, and 413 are shown. Though, it is to be appreciated that two or more dies may be used in some embodiments. In an embodiment, the dies 411, 412, and 413 are substantially similar to each other and are to be communicatively coupled to each other to provide improved capacity or otherwise improved performance. The dies 411, 412, and 413 may be any type of compute die, such as CPUs, GPUs, SoCs, ASICs, communication dies, or the like.

In an embodiment, the dies 411, 412, and 413 may include TSVs 415. The TSVs 415 allow for communicatively coupling the backside of the dies 411, 412, and 413 to the front side of the dies 411, 412, and 413. As such, communicative coupling by the bridging circuitry on the backside of the dies 411, 412, and 413 is enabled. In an embodiment, the dies 411, 412, and 413 may further comprise pads 416. The pads 416 may be coupled to the vias 408 or pads 407 of the power delivery circuitry 405. In an embodiment, the pads 416 may be hybrid bonded to the power delivery circuitry 405 in some embodiments. Though, solder or the like may be used in some embodiments.

In an embodiment, the addition of the dies 411, 412, and 413 at this point in the process flow may be referred to as being a die-last approach. That is, at least the power delivery circuitry 405 is fabricated before the dies 411, 412, and 413 are attached to the system. This enables both known-good power delivery circuitry 405 and known-good dies 411, 412, and 413 to be provided in order to improve yield and reduce costs of assembly. In some embodiments, the bridge dies 430 on the first carrier 451 are also assembled before the dies 411, 412, and 413 are attached to the system.

Referring now to FIG. 4D, a cross-sectional illustration of the second carrier 452 after the first dielectric layer 401 is extended in order to embed the dies 411, 412, and 413 is shown, in accordance with an embodiment. In the illustrated embodiment, the first dielectric layer 401 is shown as a single material. Though, in other embodiments, the portion of the first dielectric layer 401 that embeds the dies 411, 412, and 413 may be a different material than the portion of the first dielectric layer 401 that embeds the power delivery circuitry 405. The remaining portion of the first dielectric layer 401 may be applied with a lamination process or other deposition process. The first dielectric layer 401 may then be planarized so that a backside of the dies 411, 412, and 413 is substantially coplanar with the top surface of the first dielectric layer 401. The planarization may enable improved hybrid bonding in a subsequent processing operation shown in FIG. 4E.

Referring now to FIG. 4E, a cross-sectional illustration of the electronic package after the bridge dies 430 are bonded to the dies 411, 412, and 413 is shown, in accordance with an embodiment. As shown, the second carrier 452 is removed. The second carrier 452 may be removed after the bonding process between the bridge dies 430 and the dies 411, 412, and 413. In an embodiment, the first carrier 451 may also be removed after the bonding process. In an embodiment, the bonding process may be a hybrid bonding process that couples the bridge dies 430 to the TSVs 415 with a copper-to-copper bond. The second dielectric layer 402 may be bonded to the first dielectric layer 401 and/or the dies 411, 412, and 413.

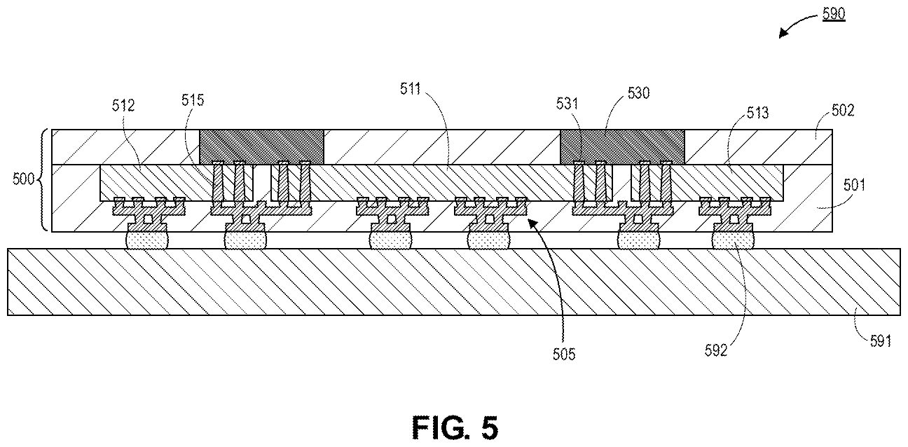

Referring now to FIG. 5, a cross-sectional illustration of a computing system 590 is shown, in accordance with an embodiment. In an embodiment, the computing system 590 comprises a board 591, such as a printed circuit board (PCB). The board 591 may be coupled to an electronic package 500 by interconnects 592. The interconnects 592 are shown as being solder balls, but it is to be appreciated that any interconnect 592 architecture may be used in various embodiments.

In an embodiment, the electronic package 500 comprises a first dielectric layer 501 and a second dielectric layer 502. In the first dielectric layer 501, a row of dies 511, 512, and 513 may be provided over power delivery circuitry 505. The dies 511, 512, and 513 may include TSVs 515. In an embodiment, three dies 511, 512, and 513 are shown, but it is to be appreciated that any number of dies may be used in some embodiments. The dies 511, 512, and 513 may be compute dies, such as CPUs, GPUs, SoCs, ASICs, communication dies, or the like.

In an embodiment, bridge dies 530 may be provided over the dies 511, 512, and 513 in the second dielectric layer 502. The bridge dies 530 may include pads 531 that are bonded to the TSVs 515. For example, a hybrid bonding process may be used in some embodiments. While bridge dies 530 are shown, it is to be appreciated that the bridge dies 530 may be replaced with HDP routing provided in the second dielectric layer 502, similar to the embodiment shown in FIG. 1. In an embodiment, the bridge dies 530 communicatively couple the dies 511, 512, and 513 together.

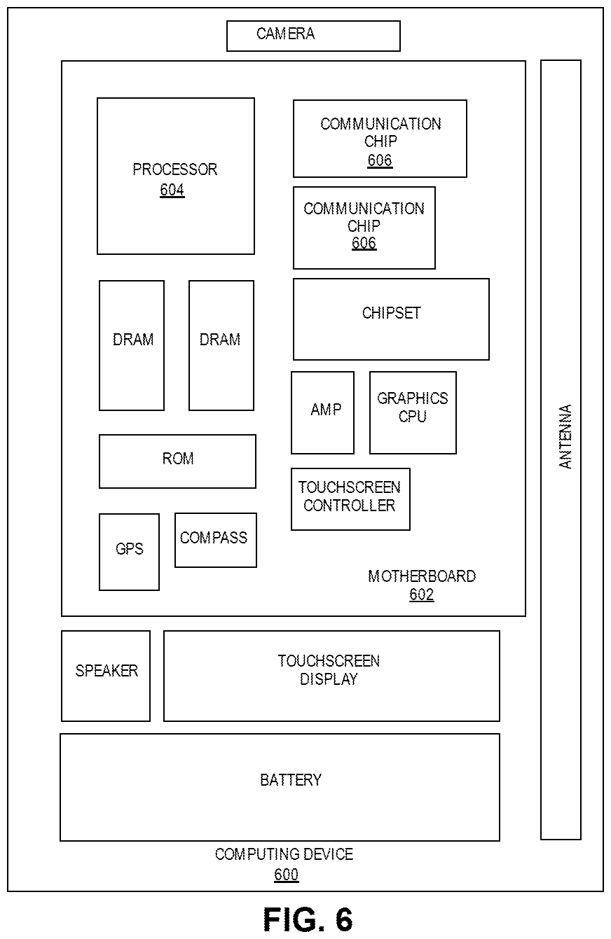

FIG. 6 illustrates a computing device 600 in accordance with one implementation of the invention. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of the invention, the integrated circuit die of the processor may be part of an electronic package that comprises a die layer with bridging circuitry on one side and power delivery circuitry on the other side, in accordance with embodiments described herein. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of the invention, the integrated circuit die of the communication chip may be part of an electronic package that comprises a die layer with bridging circuitry on one side and power delivery circuitry on the other side, in accordance with embodiments described herein.

In an embodiment, the computing device 600 may be part of any apparatus. For example, the computing device may be part of a personal computer, a server, a mobile device, a tablet, an automobile, or the like. That is, the computing device 600 is not limited to being used for any particular type of system, and the computing device 600 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an electronic package, comprising: a die layer, with a first side and a second side opposite from the first side, wherein the die layer comprises: a first die; and a second die; a bridge on the first side of the die layer, wherein the bridge communicatively couples the first die to the second die; and electrically conductive routing on the second side of the die layer.

Example 2: the electronic package of Example 1, wherein the bridge comprises conductive routing embedded in a dielectric layer.

Example 3: the electronic package of Example 1 or Example 2, wherein the bridge comprises a bridge die embedded in a dielectric layer.

Example 4: the electronic package of Examples 1-3, wherein the bridge is directly coupled to the first die and the second die without a solder interconnection.

Example 5: the electronic package of Example 4, wherein the bridge is hybrid bonded to the first die and the second die.

Example 6: the electronic package of Examples 1-5, wherein through die vias pass through the first die and the second dies.

Example 7: the electronic package of Examples 1-6, further comprising: a third die in the die layer, and wherein the bridge communicatively couples the first die to the third die.

Example 8: the electronic package of Examples 1-7, wherein the bridge is embedded in a buildup film.

Example 9: the electronic package of Examples 1-8, wherein the die layer is embedded in a buildup film.

Example 10: the electronic package of Examples 1-9, wherein the electronic package is part of a computing system for a personal computer, a server, a mobile device, a tablet, or an automobile.

Example 11: a method of assembling an electronic package, comprising: forming a bridge on a first carrier; forming power delivery routing on a second carrier; coupling a first die and a second die to the power delivery routing; embedding the first die and the second die in a dielectric; and attaching the bridge to the first die and the second die on a side of the first die and the second die opposite from the power delivery routing.

Example 12: the method of Example 11, wherein the first carrier and the second carrier comprise glass.

Example 13: the method of Example 11 or Example 12, wherein the bridge is coupled to the first die and the second die with a hybrid bonding process.

Example 14: the method of Examples 11-13, wherein the bridge is a bridge die.

Example 15: the method of Examples 11-14, wherein the bridge is conductive routing in a dielectric layer.

Example 16: the method of Examples 11-15, wherein the first carrier and the second carrier are removed from the structure.

Example 17: an electronic system, comprising: a board; an electronic package coupled to the board, wherein the electronic package comprises: a first die; a second die adjacent to the first die; an insulating layer around the first die and the second die; a bridge over the insulating layer, wherein the bridge communicatively couples the first die to the second die; and power delivery routing coupled to the first die and the second die on a side opposite from the bridge.

Example 18: the electronic system of Example 17, wherein the bridge is a bridge die.

Example 19: the electronic system of Example 17 or Example 18, wherein the bridge comprises conductive routing embedded in a dielectric layer.

Example 20: the electronic system of Examples 17-19, wherein the electronic system is part of a computing system for a personal computer, a server, a mobile device, a tablet, or an automobile.

What is claimed is:

1. An electronic package, comprising:
a die layer, with a first side and a second side opposite from the first side, wherein the die layer comprises:
a first die; and
a second die;
a bridge on the first side of the die layer, wherein the bridge communicatively couples the first die to the second die; and
electrically conductive routing on the second side of the die layer.

2. The electronic package of claim 1, wherein the bridge comprises conductive routing embedded in a dielectric layer.

3. The electronic package of claim 1, wherein the bridge comprises a bridge die embedded in a dielectric layer.

4. The electronic package of claim 1, wherein the bridge is directly coupled to the first die and the second die without a solder interconnection.

5. The electronic package of claim 4, wherein the bridge is hybrid bonded to the first die and the second die.

6. The electronic package of claim 1, wherein through die vias pass through the first die and the second dies.

7. The electronic package of claim 1, further comprising:
a third die in the die layer, and wherein the bridge communicatively couples the first die to the third die.

8. The electronic package of claim 1, wherein the bridge is embedded in a buildup film.

9. The electronic package of claim 1, wherein the die layer is embedded in a buildup film.

10. The electronic package of claim 1, wherein the electronic package is part of a computing system for a personal computer, a server, a mobile device, a tablet, or an automobile.

11. A method of assembling an electronic package, comprising:
forming a bridge on a first carrier;
forming power delivery routing on a second carrier;
coupling a first die and a second die to the power delivery routing;
embedding the first die and the second die in a dielectric; and
attaching the bridge to the first die and the second die on a side of the first die and the second die opposite from the power delivery routing.

12. The method of claim 11, wherein the first carrier and the second carrier comprise glass.

13. The method of claim 11, wherein the bridge is coupled to the first die and the second die with a hybrid bonding process.

14. The method of claim 11, wherein the bridge is a bridge die.

15. The method of claim 11, wherein the bridge is conductive routing in a dielectric layer.

16. The method of claim 11, wherein the first carrier and the second carrier are removed from the structure.

17. An electronic system, comprising:
a board;
an electronic package coupled to the board, wherein the electronic package comprises:
a first die;
a second die adjacent to the first die;
an insulating layer around the first die and the second die;
a bridge over the insulating layer, wherein the bridge communicatively couples the first die to the second die; and
power delivery routing coupled to the first die and the second die on a side opposite from the bridge.

18. The electronic system of claim 17, wherein the bridge is a bridge die.

19. The electronic system of claim 17, wherein the bridge comprises conductive routing embedded in a dielectric layer.

20. The electronic system of claim 17, wherein the electronic system is part of a computing system for a personal computer, a server, a mobile device, a tablet, or an automobile.
